(19) United States
(12) Patent Application Publication
(10) Pub. No.: US 2024/0373604 A1
(43) Pub. Date: Nov. 7, 2024

(54) COOLER FOR AN ELECTRONIC COMPONENT AND POWER MODULE COMPRISING SUCH A COOLER

(71) Applicant: Danfoss Silicon Power GmbH, Flensburg (DE)

(72) Inventors: Henning STROBEL-MAIER, Nordborg (DK); Klaus OLESEN, Nordborg (DK)

(21) Appl. No.: 18/686,995

(22) PCT Filed: Aug. 26, 2022
(86) PCT No.: PCT/EP2022/073792

§ 371 Date: Feb. 27, 2024

(30) Foreign Application Priority Data
Sep. 6, 2021 (DE) 10 2021 123 040.3

(51) Int. Cl. H05K 7/20

(52) U.S. Cl. CPC H05K 7/20927; H05K 7/20272

(57) ABSTRACT

The disclosure includes a cooler for an electronic component comprising a base plate having an outer surface and an inner surface. Channel walls are arranged on the inner surface defining fluid channels, wherein at least a first kind of channels and a second kind of channels are provided. A geometry of the first kind of channels and the second kind of channels differ such that an amount of fluid flowing through the first kind of channel is different to an amount of fluid flowing through the second kind of channel.

### CROSS-REFERENCE TO RELATED APPLICATIONS

This application is a National Stage application of International Patent Application No. PCT/EP2022/073792, filed on Aug. 26, 2022, which claims priority to German Patent Application No. 10 2021 123 040.3, filed Sep. 6, 2021, each of which is hereby incorporated by reference in its entirety.

### TECHNICAL FIELD

The invention relates to a cooler for an electronic component comprising a base plate having an outer surface and an inner surface, wherein channel walls are arranged on the inner surface defining fluid channels. An electronic component, which generates heat when in use, can be arranged on the outer surface and a coolant for transporting the heat away can be guided through the channels. Further the inventions relates to a semiconductor power module comprising such a cooler.

### BACKGROUND

During operation, electronic components such as semiconductor switches, produce heat. This heat should be removed by means of the coolant guided through the channels of a cooler, wherein the electronic component is mounted directly or indirectly on an outer surface of the cooler or rather the outer side of the base plate. Such a cooler is disclosed in U.S. Pat. No. 10,999,955 B2. The coolant can be any of a number of different fluids known in the field. Typically, water with or without minor additives may be used.

Depending on the geometry of the baseplate, it may be difficult to achieve a distribution of fluid to the fluid channels which corresponds to the cooling effect that is required. It is often the case that certain electronic components generate more heat when in service than others, or that electronic components are distributed inhomogeneously over the outer surface of the cooler. In such a case, certain parts of the cooler, those closest to the high concentration of generated heat, will require more cooling than other parts. One object of an improved cooler would therefore be that certain parts of the cooler enable more cooling than other parts In addition, it is known that it is difficult to ensure homogeneous distribution of fluid to the fluid channels in areas where this is homogenous cooling is required, since the flow through individual channels may be heavily dependent upon the distance of the channel's inlet from the source of coolant fluid, the distance of the channel's outlet from the sink of the coolant fluid, the geometry of the channel's inlet or outlet, or other factors. Another object of an improved cooler would therefore be to ensure that a there is an homogeneous distribution of fluid to the fluid channels in areas where this is homogenous cooling is required.

### SUMMARY

According to the present invention, the above mentioned objects are solved in that at least a first kind of channels and a second kind of channels are arranged on the inner surface of the baseplate, wherein a geometry of the first kind of channels and the second kind of channels differ such that an amount of fluid flowing through the first kind of channel is different to an amount of fluid flowing through the second kind of channel.

This has the effect that, for example in case of elongated coolers fed with coolant from one end, it may be possible to tailor the flow through multiple channels irrespective of how far they lie from the coolant feed. Channels of the first kind may be placed close to the coolant feed, where pressures are greatest. Alternatively or additionally, channels of the first kind may be placed where less cooling is required (for example, in areas of the base plate which correspond to gaps between heat-generating electronic components mounted on the outer side of the base plate), whilst channels of the second kind may be placed where more cooling is required (for example, in areas of the base plate which correspond to the positions of the heat-generating electronic components mounted on the outside of the base plate). In this manner, only a smaller amount of coolant is able to flow through the channels of the first kind, where minimal cooling is required, so that enough coolant is able to flow through the second kind of channels where cooling is required. Therewith, the heat is removed exactly where it is needed and yet it is ensured that all channels are supplied with at least some coolant.

In a preferred embodiment, a plurality of the fluid channels of the cooler pass fluid from a first edge of the base plate to a second edge of the base plate opposite the first edge.

In a preferred embodiment, the difference in the amount of fluid flowing through the first and second kinds of channel may be between a factor of 1.1 and 5. In particular, the difference in the amount of fluid flowing through the first and second kinds of channel may be between a factor of 1.2 and 4. In particularly preferred embodiments, the difference in the amount of fluid flowing through the first and second kinds of channel may be a factor of 2 or 3.

It is preferred that the channels are connected in parallel with a first manifold and second manifold. One of the manifolds might be used as an inlet manifold and the other manifold might be used as an outlet manifold depending on the flow direction. Usage of the manifolds simplifies the installation of the cooler and allows the use of a high number of channels.

In a preferred embodiment, the channels have the same width and/or depth. Alternatively or additionally, the thickness of the channel walls can be constant. Such a design allows several manufacturing methods, such as hot or cold forging, milling, casting or additive manufacturing methods such as 3D printing. In particular, the inventive cooler is suitable for being manufactured by hot or cold forging, since the channel structure to be formed may easily be designed to have a homogeneous channel structure without large areas of solid, unchanneled blocks (where cooling is not required), which blocks are difficult to accurately forge. The production of inventive coolers without unchanneled blocks leads to less material concentration and therefore to a reduced mass of the cooler. This is beneficial in particular if the cooler is used in mobile devices like cars, for example.

In some cases, the channel geometry, for example the channel width, may vary along the flow path in order to compensate for the calorimetric effects that heat up the fluid (typically by 10K) as it absorbs thermal energy from the heat producing devices. This varying channel geometry increases the cooling efficiency along the flow path ensuring a homogeneous temperature distribution in the setup. Without this geometric compensation, the calorimetric effects can cause temperature gradients in the setup.

In a preferred embodiment, the first kind of flow channel has a first flow resistance and the second kind of flow channel has a second flow resistance, wherein the first flow resistance and the second flow resistance are different. The flow resistance can be influenced by the geometry of the channels or the channel walls. By means of different flow resistances, it is relatively easy to affect the amount of flow flowing through the channels. This, for example, allows the cooling effect provided by a particular channel to reflect the heat generated by the electronic components mounted on the corresponding area on the outer surface of the baseplate, and thus the cooling is tailored to the heat generation. In one extreme embodiment, a channel may be created which is blocked, and so has an infinite flow resistance and no flow through it. However, such blocked channels are avoided since they would result in “dead-water” regions. In such dead-water regions there is no movement of the fluid, and this can lead to various corrosion problems. If the flow resistance is high, even a high differential pressure drop leads to a small amount of flow wherein in case of a low flow resistance the same differential pressure drop results in a higher amount of flow through the channel. This means, that by varying the flow resistance, the amount of flow flowing through the channels can be affected.

Preferably, the first flow resistance and/or the second flow resistance of the channels depends on a fluid flow direction. This difference in flow resistance depending on fluid flow direction may described by the parameter “Diodicity”, D, which is the relation between the backward-flow pressure drop and the forward-flow pressure drop, thus:

$$D = \frac{Δ {P}_{backward}}{Δ {P}_{forward}}$$

A diodicity which is not equal to unity describes the situation in which the amount of fluid flowing through the respective channels is dependent on a fluid flow direction. For example, the amount of fluid flowing in the one direction may be between 1.2 to 4 times the amount of fluid flowing through the same channel in the opposite direction.

In a preferred embodiment, the channels of the first kind of channels have a geometry such that when fluid flows through the channel in a first direction a certain amount of the fluid is deflected, and when the fluid flows through the channel in a second direction, opposite to the first direction, no deflection takes place.

By “deflection” is meant that a proportion of the fluid flowing in a particular channel is separated and then forced into a different flow direction from the initial direction of flow. The separating and forcing may be enabled by dividing the channel and forming one of the channel divisions so that it has a different direction. In some embodiments, the deflected flow may be re-combined with the original undeflected flow, but at an angle corresponding to the deflection. This re-combination is designed to interfere with the smooth flow of the coolant in the channel, thus increasing the flow resistance.

It might be preferred that the channels of the second kind of channel have a geometry such that only in one flow direction a certain amount of the flow is deflected, wherein in the same flow direction the flow through the first kind of channels is not deflected. Therewith, the difference between the resistance of the first kind of channels and the flow resistance of the second kind of channels is increased.

In an alternative embodiment, the channels of the second kind of channels have a meandering geometry. The flow resistance of the second kind of channels is then independent of the flow direction.

Advantageously the channels are arranged in patterns, wherein in each pattern channels of the same kind are arranged. By “arranged in patterns” is meant that a plurality of instances of a particular form of channel are arranged on the base plate displaced in a first direction, or a first direction and a second direction, to form a relatively homogenous array of channels.

In a preferred embodiment the cooler comprises a third kind of channel, which channel comprises a first portion and a second portion, in series with the first portion, wherein the geometry of the first portion is such that when fluid flows through the channel in a first direction a certain amount of the fluid is deflected and the geometry of the second portion is such that when the fluid flows through the channel in a second direction, opposite to the first direction, a certain amount of the fluid is deflected.

The amount of fluid flowing through this third kind of channels is then always small, independent of the fluid flow direction but in comparison to blocked channels, dead-water regions are avoided. A cooler comprising such channels would be able to provide tailored cooling irrespective of the direction of fluid flowing through the cooler.

When a portion of the flowing fluid is deflected so much that its direction of flow becomes substantially opposite to the direction of the initial flow direction, a reverse flow is established.

Advantageously the channel walls of the first and/or second and/or third kind of channels comprise structures causing a reverse flow in one flow direction and a straight flow in the opposite direction. This results in a high diodicity.

The reverse flow can be caused by channels wherein the first and/or second and/or third kind of channels comprise alternating curved sections, wherein a reversing channel is located at each curved section. Then the main flow meanders through the channels, wherein the deflected flow, which is only a small amount of the flow, is reversed through the reversing channel at each curved section.

It is preferred that the first and/or second and/or third kind of channels comprise an elongated section between each curved section. A longer length of the elongated sections results in less curved sections and a shorter channel.

Preferably, an incoming end of the outer wall of the reversing channel is flush with an outer wall of the elongated section. Then the flow can glide along the channel walls and disturbances like turbulences are avoided.

In a preferred embodiment of the cooler, the base plate is rectangular having a width and a length, wherein the length is at least three times the width. Such a shape is typically used for inverters in the automotive area.

It is preferred that the base plate is manufactured by hot- or cold forging. Such production processes are inexpensive and reliable, and typically use metal. Forging works with very high pressing forces that force the material to flow into the required geometries defined by a forging tool. Forging is particularly well-suited to forming structures with relative homogeneous arrays of protrusions (such as walls defining cooling channels), whereas inhomogeneous arrays of protrusions may result in unavoidable warping of the forged item or incomplete flow into the required geometries. The inventive cooler described above lends itself to such a manufacturing process, since it enables the design of a homogenous array of cooling channels, but where cooling is restricted to the areas in which it is required.

The above mentioned objects are solved by a semiconductor power module comprising a cooler as described above. The semiconductor power module comprises electronic components such as semiconductor switches which are cooled by the cooler. Such semiconductor switches may comprise insulated-gate bipolar transistors (IGBTs), metal-oxide-semiconductor field-effect transistors (MOSFETs) or other devices known in the field, and may utilize silicon-based semiconductors or wide-bandgap semiconductors such as silicon carbide (SiC) or gallium nitride (GaN).

### BRIEF DESCRIPTION OF THE DRAWINGS

Preferred embodiments of the invention will now be described with reference to the figures, wherein:

FIG. 1: shows a first embodiment of a base plate of a cooler,

FIG. 2: shows a second embodiment of the base plate of a cooler and

FIG. 3: shows a third embodiment of the base plate of a cooler.

### DETAILED DESCRIPTION

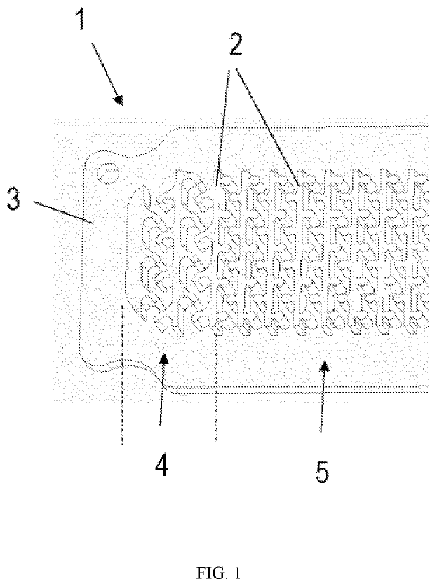

In FIG. 1 a section of a base plate 1 is shown. Channel walls 2 are arranged on an inner side 3 of the base plate 1. Fluid channels of a first kind 4 and of a second kind 5 are formed between the channels walls 2.

The first kind of channels 4 have a geometry such that in one fluid flow direction, for example from the bottom of the figure to the top, a certain amount of the fluid flow is deflected. In this flow direction a flow resistance of the channels is higher than in the opposite direction (from the top if the Figure to the bottom). This has the effect that in an amount of fluid flowing through the first kind of channels 4 in one direction is less than in the opposite direction.

The second kind of channels 5 have a geometry such, that the flow is meandering through the channels, wherein the flow resistance and the amount of flow is independent of the flow direction.

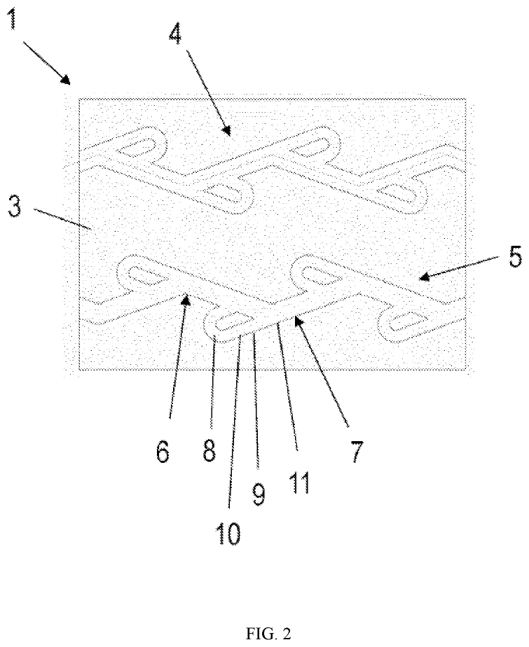

In FIG. 2 a section of a base plate 1 according to a second embodiment is shown. In this embodiment, the flow direction of the coolant in the channels is from the left of the figure to the right. Only one channel of the first kind 4 and one channel of the second kind 5 are depicted. The geometry of the first kind of channels 4 and the second kind of channels 5 is the same, but they are oriented in an opposite direction.

The channels comprise curved sections 6 and elongated sections 7 between each curved section 6. Reversing channels 8 are located at each curved section 6. Such a structure causes a reverse flow in one direction and a more or less straight flow in the opposite direction. In other words, the channels comprise a flow resistance that depends on the flow direction.

To avoid turbulences, an incoming end 9 of an outer wall 10 of the reversing channel 8 is flush with an outer wall 11 of the elongated section 7

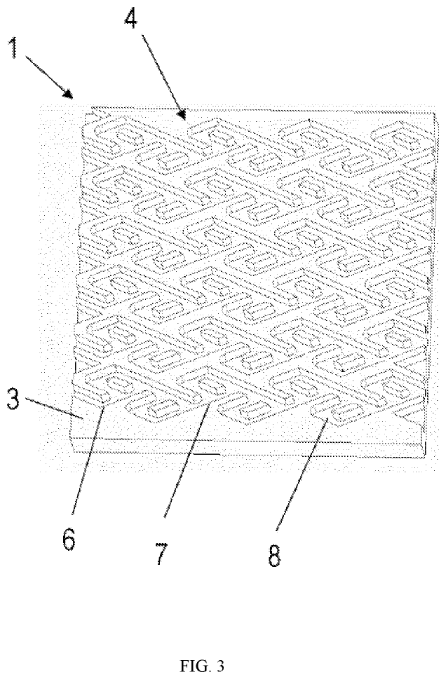

In FIG. 3 a section of a base plate 1 according to a third embodiment is shown. Only channels of the first kind 4 are depicted. In contrast to the embodiment shown in FIG. 2, the edges of the curved sections are made more angular. All the channels have the same width and depth and a thickness of the channel walls 2 is constant. Therefore, such a structure can be made easily by hot- or cold forging. In this embodiment, fluid flowing from right to left across the Figure would experience a higher flow resistance than fluid flowing in the opposite direction.

While the present disclosure has been illustrated and described with respect to a particular embodiment thereof, it should be appreciated by those of ordinary skill in the art that various modifications to this disclosure may be made without departing from the spirit and scope of the present disclosure.

While the present disclosure has been illustrated and described with respect to a particular embodiment thereof, it should be appreciated by those of ordinary skill in the art that various modifications to this disclosure may be made without departing from the spirit and scope of the present disclosure.

1. A cooler for an electronic component comprising a base plate having an outer surface and an inner surface, wherein channel walls are arranged on the inner surface defining fluid channels, wherein at least a first kind of channels and a second kind of channels are provided, wherein a geometry of the first kind of channels and the second kind of channels differ such that an amount of fluid flowing through the first kind of channel is different to an amount of fluid flowing through the second kind of channel.

2. The cooler according to claim 1, wherein the difference in the amount of fluid flowing through the first kind of channel and the second kind of channel is between a factor of 1.1 and 5.

3. The cooler according to claim 1, wherein the channels have the same width and/or depth.

4. The cooler according to claim 1, wherein a thickness of the channel walls is constant.

5. The cooler according to claim 1, wherein the first kind of channel has a first flow resistance and the second kind of channel has a second flow resistance, wherein the first flow resistance and the second flow resistance are different.

6. The cooler according to claim 1, wherein the first flow resistance and/or the second flow resistance of the channels depends on a fluid flow direction.

7. The cooler according to claim 1, wherein the channels of the first kind of channel have a geometry such that when fluid flows through the channel in a first direction a certain amount of the fluid is deflected, and when the fluid flows through the channel in a second direction, opposite to the first direction, no deflection takes place.

8. The cooler according to claim 1, wherein the channels of the second kind of channels have a meandering geometry.

9. The cooler according to claim 1, wherein the first kind of channels and the second kind of channels are arranged in patterns.

10. The cooler according to claim 1, wherein the cooler comprises a third kind of channel, which channel comprises a first portion and a second portion, in series with the first portion, wherein the geometry of the first portion is such that when fluid flows through the channel in a first direction a certain amount of the fluid is deflected and the geometry of the second portion is such that when the fluid flows through the channel in a second direction, opposite to the first direction, a certain amount of the fluid is deflected.

11. The cooler according to claim 1, wherein the channel walls of the first and/or second and/or third kind of channels comprise structures causing a reverse flow in one flow direction and a straight flow in the opposite direction.

12. The cooler according to claim 1, wherein the first and/or second and/or third kind of channels comprise alternating curved sections, wherein a reversing channel is located at each curved section.

13. The cooler according to claim 12, wherein the first and/or second and/or third kind of channels comprise an elongated section between each curved section.

14. The cooler according to claim 12, wherein an incoming end of an outer wall of the reversing channel is flush with an outer wall of the elongated section.

15. The cooler according to claim 1, wherein the base plate is rectangular having a width and a length, wherein the lengths is at least three times the width.

16. The cooler according to claim 1, wherein the base plate is manufactured by hot- or cold forging.

17. A semiconductor power module comprising a cooler according to claim 1.
